(19) United States
(12) Patent Application Publication
(10) Pub. No.: US 2024/0145422 A1
(43) Pub. Date: May 2, 2024

(54) LIQUID-REPELLING COATING FOR UNDERFILL BLEED OUT CONTROL

(71) Applicant: Micron Technology, Inc., Boise, ID (US)

(72) Inventors: Jungbae Lee, Taichung (TW); Bong Woo Choi, Singapore (SG)

(21) Appl. No.: 17/974,435

(22) Filed: Oct. 26, 2022

(51) Int. Cl. H01L 23/00; H01L 25/065

(52) U.S. Cl. CPC H01L 24/32; H01L 24/16; H01L 24/27; H01L 24/48; H01L 24/73; H01L 25/0657; H01L 2224/16145; H01L 2224/16245; H01L 2224/26175; H01L 2224/27013; H01L 2224/32145; H01L 2224/32245; H01L 2224/48147; H01L 2224/48249; H01L 2224/73204; H01L 2224/73215; H01L 2224/73253; H01L 2224/73265; H01L 2225/06506; H01L 2225/0651; H01L 2225/06513; H01L 2225/06517; H01L 2225/06524; H01L 2225/06527; H01L 2225/06562; H01L 2924/1431; H01L 2924/1436; H01L 2924/1438

(57) ABSTRACT

A semiconductor device assembly is provided. The assembly includes a substrate having a plurality of contact pads disposed at a coupling surface. A semiconductor die is coupled with the substrate at the plurality of contact pads, and a liquid-repelling material resistant to wetting by an underfill material is disposed at the coupling surface of the substrate surrounding a periphery of the semiconductor die. The underfill material is disposed between the semiconductor die and the substrate. The underfill material includes a fillet between the semiconductor die and the liquid-repelling material. As a result, the expansion of the underfill material beyond the semiconductor die may be controlled.

### TECHNICAL FIELD

The present disclosure generally relates to semiconductor device assemblies, and more particularly relates to a liquid-repelling coating for underfill bleed out control.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of an example semiconductor device assembly.

FIG. 2 illustrates a simplified schematic cross-sectional view of a semiconductor device assembly in accordance with an embodiment of the present technology.

FIGS. 3-7 illustrate simplified schematic partial plan views of a series of steps for fabricating semiconductor device assemblies in accordance with an embodiment of the present technology.

FIG. 8 illustrates a simplified schematic cross-sectional view of a semiconductor device assembly in accordance with an embodiment of the present technology.

FIG. 9 illustrates a schematic view of a system that includes a semiconductor device assembly configured in accordance with an embodiment of the present technology.

FIG. 10 illustrates a method of making a semiconductor device assembly in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device. This development, however, may not be sustainable due to various challenges that arise from designing semiconductor devices with high circuit density. Thus, additional techniques may be required to continue the growth in capability of semiconductor devices.

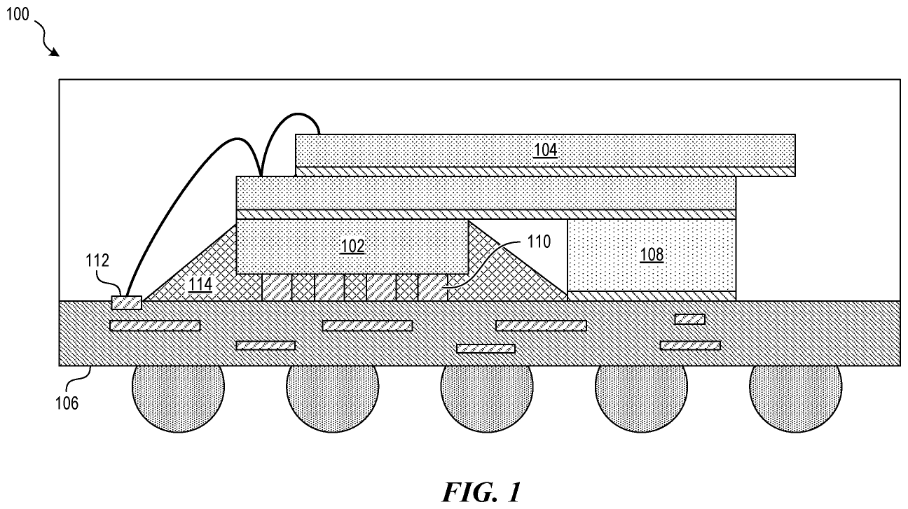

One such technique is to implement multiple circuit components within a single package. While packaged semiconductor devices may enable compact semiconductor devices to be developed, the proximity of the multiple circuit components to one another may create interferences. For example, a semiconductor die may be mounted to a substrate. An underfill material may be disposed between the semiconductor die and the substrate. During dispensing, the underfill material may expand across the substrate and onto other circuit components, which may affect the performance of these circuit components. Thus, some semiconductor device assemblies may be unreliable. One such semiconductor device assembly is illustrated by way of example in FIG. 1.

As can be seen with reference to FIG. 1, a semiconductor device assembly 100 has multiple semiconductor dies, including a logic die 102 and memory dies 104, assembled onto a substrate 106. The logic die 102 may be mounted to the substrate 106, and the memory dies 104 may be mounted on the logic die 102 and a spacer 108. The spacer 108 may be adhered to the substrate 106 and have a height roughly equivalent to the height of the logic die 102 to enable the memory dies 104 to be mounted flat on the substrate 106 and the spacer 108. The logic die 102 may electrically couple with the substrate 106 (e.g., in a flip-chip arrangement) through interconnects 110 (e.g., solder joints, conductive pillars, etc.) formed between the contacts on the substrate 106 and corresponding contacts on the logic die 102. The substrate 106 further incudes wire bond pads 112 at which the memory dies 104 couple with the substrate 106 through wires. The substrate 106 may include package-level contact pads for providing external connectivity (e.g., through solder balls) to the logic die 102 or the memory dies 104 (e.g., power, ground, and input/output (I/O) signals) through traces, lines, vias, and other electrical connection structures (illustrated schematically in FIG. 1) in the substrate 106 that electrically connect to the wire bonds pads 112 and the contacts at which the interconnects 110 are implemented.

An underfill material 114 (e.g., capillary underfill) is provided between the logic die 102 and the substrate 106 to provide electrical insulation to the interconnects 110 and mechanically support the coupling between the logic die 102 and the substrate 106. The underfill material 114 may be disposed at a side of the logic die 102 between the logic die 102 and the substrate, and the underfill material 114 may fill into capillaries between the logic die 102 and the substrate 106. In addition to flowing into capillaries between the logic die 102 and the substrate 106, the underfill material 114 may flow away from the logic die 102, resulting in a portion of underfill material 114 outside of the footprint of the logic die 102 (e.g., the fillet).

One drawback to this arrangement is the challenge associated with controlling the flow of the underfill material 114 away from the logic die 102. For example, the underfill material 114 may be dispensed at a side of the logic die 102, and the underfill material 114 may flow between the logic die 102 and the substrate 106. Based on its properties, the underfill material 114 may also flow away from the logic die 102 and across the substrate 106. In some cases, the underfill material 114 may expand away from the logic die 102 to the wire bond pads 112 or the spacer 108. As a result, the wire bond pads 112 may be contaminated with the underfill material 114, which may compromise the wire bond pads 112. Alternatively or additionally, the underfill material 114 may expand out to the spacer 108, thereby impacting adhesion between the space 108 and the substrate 106 or creating a non-uniform surface roughness under the spacer 108, which may compromise the structural integrity of the stack of semiconductor dies.

To address these drawbacks and others, various embodiments of the present application provide semiconductor device assemblies that implement a liquid-repelling (e.g., hydrophobic) material for underfill bleed out control. A semiconductor device assembly is provided that includes a substrate having a plurality of contact pads disposed at a coupling surface. A semiconductor die is coupled with the substrate at the plurality of contact pads, and a coating of liquid-repelling material resistant to wetting by an underfill material is disposed at the coupling surface of the substrate surrounding a periphery of the semiconductor die. For example, the liquid-repelling material may have a wetting contact angle of greater than 45, 60, 70, 80, 90, 100, 110, 120, 130, 140, or 150 degrees with respect to the underfill material. The underfill material is disposed between the semiconductor die and the substrate. The underfill material includes a fillet between the semiconductor die and the coating of liquid-repelling material. As a result, the expansion of the underfill material beyond the semiconductor die may be controlled.

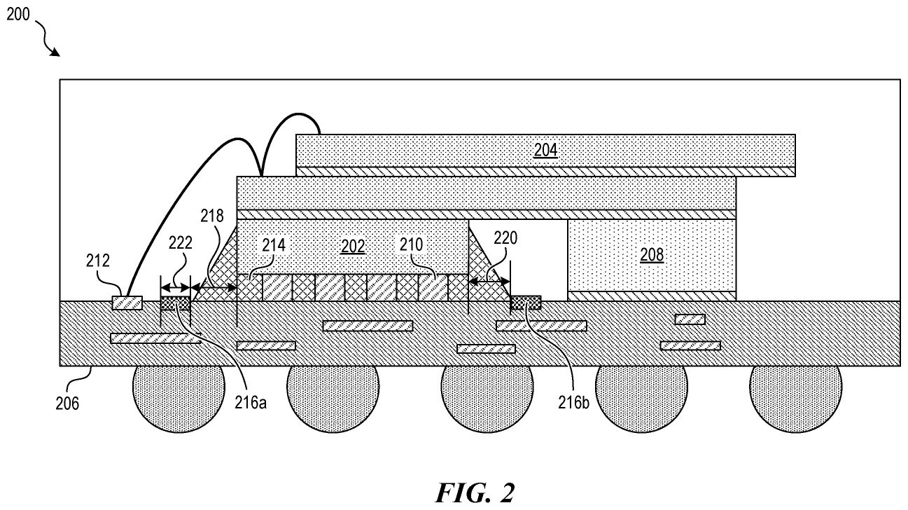

FIG. 2 illustrates a simplified schematic cross-sectional view of a semiconductor device assembly 200 in accordance with an embodiment of the present technology. As can be seen with reference to FIG. 2, assembly 200 can include multiple semiconductor dies (e.g., a logic die 202 and memory dies 204) assembled onto a substrate 206. In some implementations, the semiconductor device assembly 200 may correspond to a memory device. The logic die 202 is mounted (e.g., in a flip-chip arrangement) onto the substrate 206 at contact pads at the surface of the substrate 206. A spacer 208 is adhered to the substrate 206, and the memory dies 204 are mounted on the logic die 202 and the spacer 208. The logic die 202 may couple to the substrate 206 through interconnects 210 implemented between the contact pads at an upper surface of the substrate 206 and contact pads at the logic die 202. The substrate 206 may further include wire bond pads 212 at which the memory dies 204 couple to the substrate 206 through wires. Package-level contact pads at a lower surface of the substrate 206 may connect with the contact pads and wire bond pads 212 at the upper surface through circuitry (e.g. traces, lines, vias, and other connection structures) to provide external connectivity (e.g., through solder balls) to the semiconductor dies (e.g., power, ground, and I/O signals). An underfill material 214 (e.g., capillary underfill) can be provided between the logic die 202 and the substrate 206 to provide electrical insulation to the interconnects 210 and structurally support the stack of semiconductor dies.

In accordance with one aspect of the present disclosure, the assembly 200 can further include a coating of liquid-repelling material 216 (e.g., a first portion of the coating of liquid-repelling material 216a and a second portion of the coating of liquid-repelling material 216b) at least partially surrounding a periphery of the logic die 202. The coating of liquid-repelling material 216 can be configured (e.g., by selecting a lateral distance 218 and a lateral distance 220 from the sides of the logic die 202) to constrain a fillet of the underfill material 214 such that it covers at least a portion of (e.g., at least half of, at least two thirds of, substantially all of, etc.) the vertical sidewalls of the logic die 202 (e.g., based on the slope angle of the underfill material 214 due to the coating of liquid-repelling material 216 resisting wetting by the underfill material 214, an adhesion of the underfill material 214 to the logic die 202, a viscosity of the underfill material 214, a volume of the underfill material 214, etc.). The liquid-repelling material may be any appropriate material that is resistive to wetting by the underfill material 214 (e.g., polytetrafluoroethylene (PTFE), paraffin, carnauba, lithium-calcium, sulphonates, and the like). As the underfill material 214 extends to the coating of liquid-repelling material 216, the underfill material 214 may begin to bead instead of extending over the coating of liquid-repelling material 216. In this way, the coating of liquid-repelling material 216 may retain the underfill material 214 due to its tendency to resist wetting instead of merely providing a physical barrier (e.g., a dam) to retain the underfill material 214. Thus, the coating of liquid-repelling material 216 may be a thin coating, for example, having a thickness less than 10 microns. For instance, an upper surface of the liquid-repelling material 216 may have a height less than 10 microns from the substrate 206.

The liquid-repelling material may be used to coat a portion of the upper surface of the substrate 206. For example, the coating of liquid-repelling material 216 may form an annulus (e.g., rectangular annulus) that surrounds the periphery of the logic die 202 and separates the underfill material 214 from the spacer 208 or the wire bond pads 212. A first portion of the coating of liquid-repelling material 216a and a second portion of the coating of liquid-repelling material 216b may be displaced a same distance or a different distance from the sides of the logic die 202. The first portion of the coating of liquid-repelling material 216a may be disposed closest to a side of the logic die 202 at which the underfill material 214 is dispensed for flowing between the logic die and the substrate 206, and the second portion of the coating of liquid-repelling material 216b may be disposed closest to an opposite side of the logic die 202 at which the underfill material 214 is not dispensed. In some cases, the underfill material 214 may expand farther from the logic die 202 at a side of the logic die 202 at which the underfill material 214 is dispensed. Given this tendency, the first portion of the coating of liquid-repelling material 216a may be disposed from the logic die 202 by an amount greater than the second portion of the coating of liquid-repelling material 216b. For example, the first portion of the coating of liquid-repelling material 216a may be disposed a lateral distance 218 of roughly 300 microns (e.g., within 1 micron, within 5 microns, within 10 microns, etc.) from the logic die 202, and the second portion of the coating of liquid-repelling material 216b may be disposed a lateral distance 220 of roughly 100 microns (e.g., within 1 micron, within 5 microns, within 10 microns, etc.) from the logic die 202.

The coating of liquid-repelling material 216 may be configured with a particular width 222 effective to retain the underfill material 214, for example, at least 200 microns. A wider coating of liquid-repelling material 216 may provide a larger surface at which the underfill material 214 may bead to form a retaining barrier. For instance, even if the underfill material 214 successfully wets and extends over an inner portion of the coating of liquid-repelling material 216, the underfill material 214 may bead at an outer portion of the coating of liquid-repelling material 216, and the underfill material 214 may not extend beyond the coating of liquid-repelling material 216 (e.g., to the wire bond pads 212 or the spacer 208). In some cases, the width 222 of the coating of liquid-repelling material 216 may be uniform throughout the coating of liquid-repelling material 216. In other cases, however, the width 222 may vary across different portions of the coating of liquid-repelling material 216. The maximum expansion of the underfill material 214 may be equivalent to a sum of the lateral distance (e.g., lateral distance 218 or lateral distance 220) of the coating of liquid-repelling material 216 away from the logic die 202 and the width of the coating of liquid-repelling material 216. Thus, in implementations where the lateral distance 218 between the coating of liquid-repelling material 216 and the logic die 202 is roughly 300 microns and the width 222 of the coating of liquid-repelling material is roughly 200 microns (e.g., within 1 micron, within 5 microns, within 10 microns, etc.), the maximum expansion of the underfill material 214 away from the logic die 202 may be roughly 500 microns (e.g., within 1 micron, within 5 microns, within 10 microns, etc.).

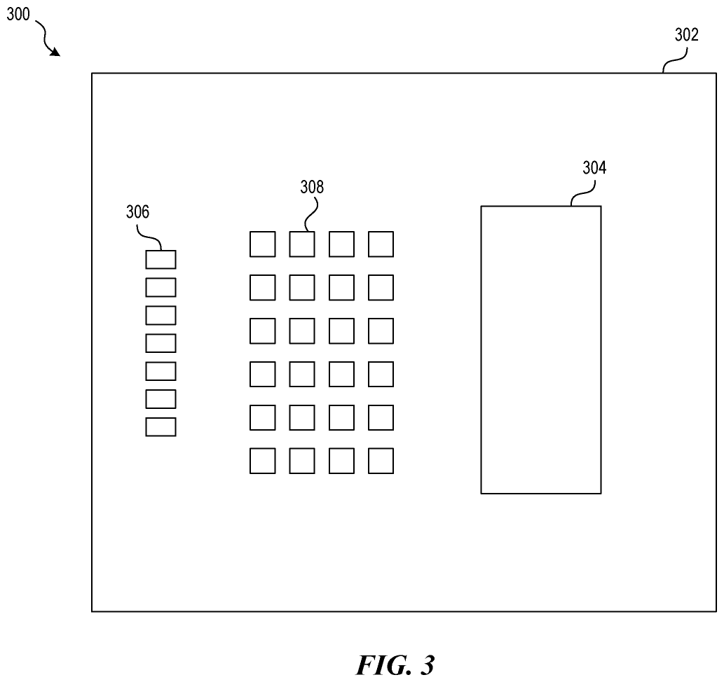

FIGS. 3-7 illustrate simplified schematic partial plan views of a series of steps for fabricating semiconductor device assemblies in accordance with an embodiment of the present technology. In some embodiments, the fabrication may be performed at the wafer-level, panel-level, strip-level, package-level, or die-level. Thus, in some embodiments, multiple semiconductor devices may be fabricated on a single substrate, and the multiple devices may be separated from one another during fabrication. In other embodiments, the substrates may be pre-singulated substrates, and a single semiconductor device may be fabricated on the substrate. For simplicity, the steps for fabricating semiconductor device assemblies are illustrated with respect to a single packaged semiconductor device in FIGS. 3-7.

Beginning with FIG. 3 at stage 300, a substrate 302 is provided. A spacer 304 is adhered to the substrate 302. The substrate 302 includes a plurality of wire bond pads 306 configured to electrically couple one or more semiconductor dies and the substrate 302 through one or more wires. The substrate 302 further includes a plurality of contact pads 308 arranged to align with contact pads at one or more semiconductor dies. The wire bond pads 306 and the contact pads 308 couple with a plurality of package-level contacts through internal circuitry, including traces, lines, vias, and other electrical connection structures.

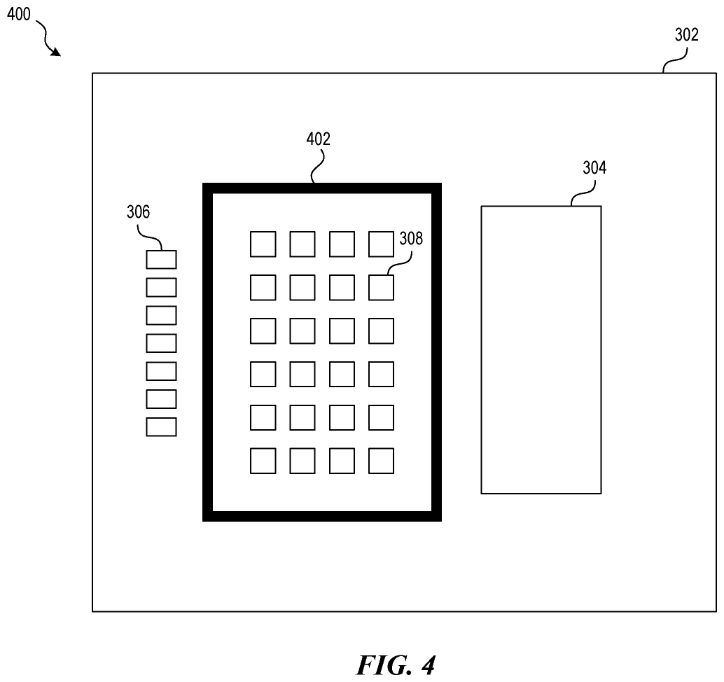

Turning to FIG. 4 at stage 400, a coating of liquid-repelling material 402 can be disposed around the plurality of contact pads 308 configured to accept one or more semiconductor dies. The coating of liquid-repelling material 402 can be configured (e.g., by selecting a thickness, width, and lateral distance from the sides of the semiconductor die that will be coupled with the plurality of contact pads 308) to constrain a fillet of underfill material such that it does not extend beyond the coating of liquid-repelling material 402. The coating of liquid-repelling material 402 may at least partially surround the contact pads 308 or the one or more semiconductor dies disposed thereat. In this regard, the coating of liquid-repelling material 402 can be generally annular (e.g., a rectangular annulus), as illustrated in FIG. 4, such that it continuously surrounds the contact pads 308 or the one or more semiconductor dies disposed thereat. In alternative embodiments, however, the coating of liquid-repelling material 402 need not be completely continuous (e.g., it may include one or more openings or be formed by multiple discrete and disconnected elements).

The coating of liquid-repelling material 402 may be disposed through any appropriate technique. For example, the coating of liquid-repelling material 402 may be disposed through masking, screen printing, three-dimensional (3D) printing, or dispensing. In one embodiment, disposing the coating of liquid-repelling material 402 may include a combination of masking, etching, and depositing the liquid-repelling material to create the coating of liquid-repelling material 402. In another embodiment, a stencil may be provided over the surface of the substrate 302, and the liquid-repelling material may be deposited in specific locations based on the stencil (e.g., using a squeegee). In another embodiment, the coating of liquid-repelling material 402 may be disposed through 3D printing. In yet another embodiment, the liquid-repelling material may be selectively dispensed in select locations to create the coating of liquid-repelling material 402, for example, through microdispensing. In some cases, the coating of liquid-repelling material 402 may be implemented at least partially within the substrate 302. For example, the substrate 302 may be etched to create one or more openings within the substrate 302, and the liquid-repelling material may be disposed at least in the one or more openings. In aspects, the coating of the liquid-repelling material 402 may be substantially coplanar with the surface of the substrate 302 (e.g., having an upper surface protruding from the surface of the substrate by less than 1 micron, 5 microns, 10 microns, etc.).

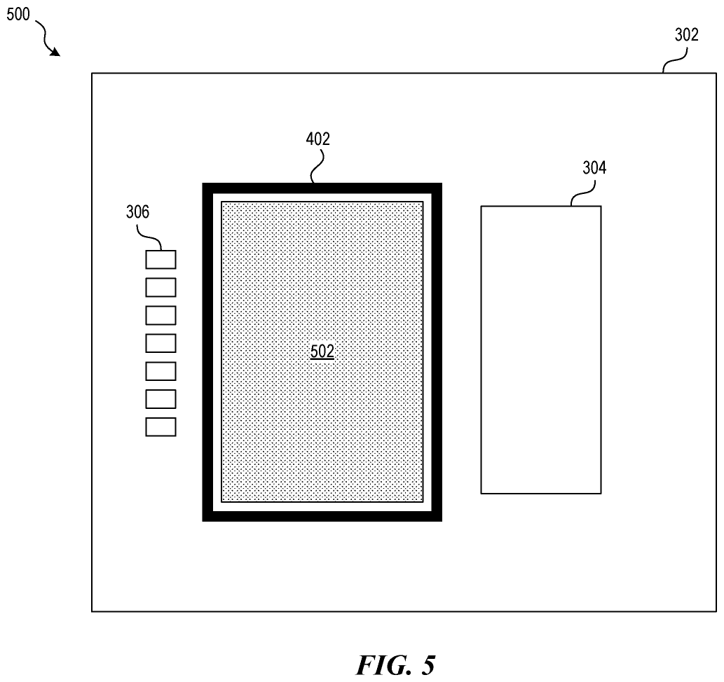

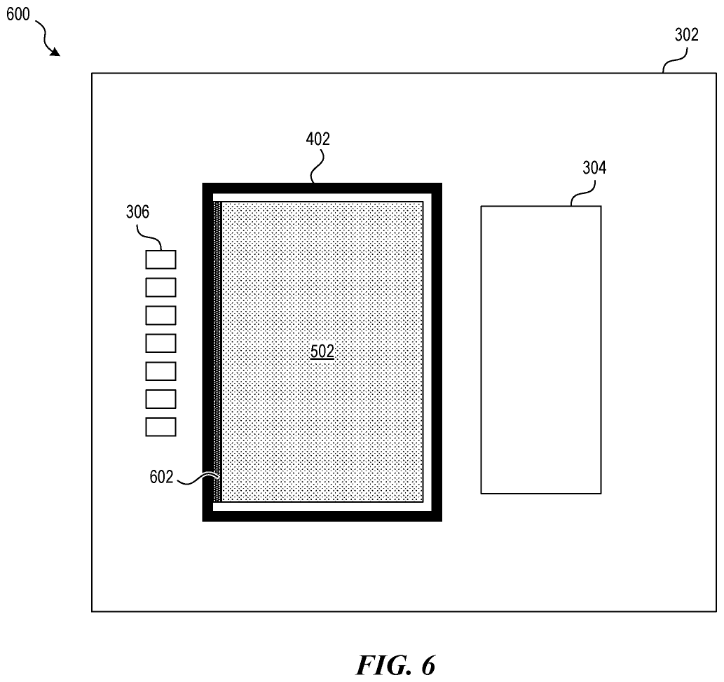

Turning next to FIG. 5 at stage 500, one or more semiconductor dies (e.g., a single die or a stack of dies), such as semiconductor die 502, can be provided over and electrically coupled (e.g., by a corresponding plurality of interconnects, such as solder balls, copper pillars, copper bumps, direct Cu—Cu cold welds, etc.) to the plurality of contact pads at the substrate 302. A periphery of the semiconductor die 502 may be surrounded by the coating of liquid-repelling material 402. Turning now to FIG. 6 at stage 600, underfill material 602 is dispensed between the semiconductor die 502 and the substrate 302 at least at a side of the semiconductor die 502. The underfill material 602 may be dispensed between the semiconductor die 502 and the substrate 302 at one or more sides of the semiconductor die 502. In some cases, the underfill material 602 may be dispensed between the semiconductor die 502 and the substrate 302 at least at a side of the semiconductor die 502 that is a greatest distance from the coating of liquid-repelling material 402. In doing so, the underfill material 602 may be expanded over a larger area at a location where it is most likely to expand away from the semiconductor die 502 to ensure that the coating of liquid-repelling material 402 retains the underfill material 602. By configuring a width and lateral spacing (e.g., from an outer vertical surface of the semiconductor die 502) of the coating of liquid-repelling material 402, the size and shape of the fillet of underfill material 602 formed adjacent each side of each semiconductor die 502 can be controlled.

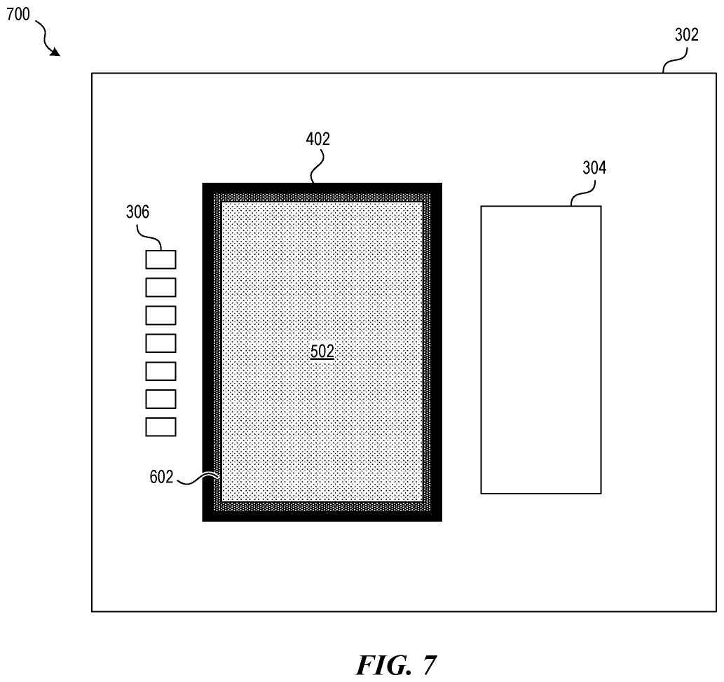

Turning next to FIG. 7 at stage 700, the underfill material 602 may flow at least between the semiconductor die 502 and the substrate 302 to insulate interconnects that electrically couple the semiconductor die 502 to the substrate 302 and structurally support the semiconductor die 502. As the underfill material 602 flows between the semiconductor die 502 and the substrate 302, additional amounts of the underfill material 602 may be disposed between the semiconductor die 502 at the substrate 302 at one or more side of the semiconductor die 502. The underfill material 602 may flow through capillary action to fill openings between the semiconductor die 502 and the substrate 302. The underfill material 602 may be retained within the coating of the liquid-repelling material 402 to separate the underfill material 602 from the spacer 304 or the plurality of wire bond pads 306.

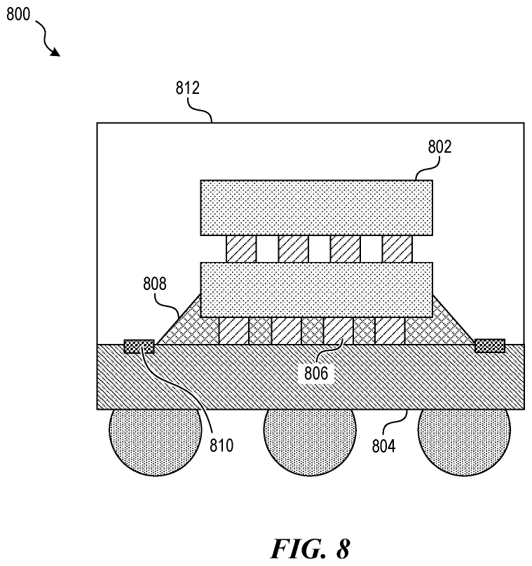

Although the foregoing example semiconductor device assemblies have been illustrated with a particular configuration of semiconductor dies or package components, in other examples, semiconductor device assemblies may be provided with a different configuration of semiconductor dies or with a different set of packages. One such semiconductor device assembly 800 in accordance with an embodiment of the present technology is illustrated in the simplified schematic cross-sectional view of FIG. 8. As can be seen with reference to FIG. 8, the semiconductor device assembly 800 can include a semiconductor die 802 assembled onto a substrate 804 (e.g., in a flip-chip arrangement). Interconnects 806 may be formed between the semiconductor die 802 and the substrate 804. The substrate 804 can further include package-level contact pads that provide external connectivity (e.g., via solder balls) to the semiconductor die 802 (e.g., power, ground, and I/O signals) through traces, lines, vias, and other electrical connection structures (not illustrated) in the substrate 804 that electrically connect the package-level contact pads to contact pads at an upper surface of the substrate 804. An underfill material 808 (e.g., capillary underfill) can be provided between the semiconductor die 802 and the substrate 804 to provide electrical insulation to the interconnects 806 and structurally support the semiconductor die 802.

In accordance with one aspect of the present disclosure, the assembly 800 can further include a coating of liquid-repelling material 810 that at least partially surrounds the semiconductor die 802. The coating of liquid-repelling material 810 can be configured (e.g., by selecting a thickness, width, and lateral distance from the vertical sides of the semiconductor die 802) to constrain a fillet of the underfill material 808 and prevent the underfill material 808 from contaminating other components at the substrate 804. The assembly 800 can further include an encapsulant material 812 (e.g., mold resin compound or the like) that at least partially encapsulates the semiconductor die 802 and the substrate 804 to prevent electrical contact therewith and provide mechanical strength and protection to the assembly.

Although the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, e.g., a vertical stack of semiconductor dies, a plurality of semiconductor dies, a single semiconductor die, mutatis mutandis.

In accordance with one aspect of the present disclosure, the semiconductor devices illustrated in the assemblies of FIGS. 2-8 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

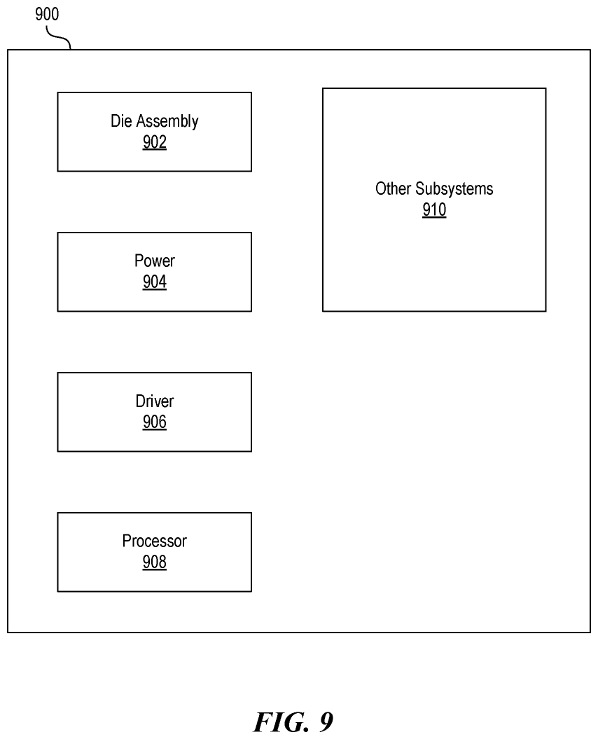

Any one of the semiconductor devices and semiconductor device assemblies described above with reference to FIGS. 2-8 can be incorporated into any of a myriad of larger and/or more complex systems, a representative example of which is system 900 shown schematically in FIG. 9. The system 900 can include a semiconductor device assembly 902 (e.g., or a discrete semiconductor device), a power source 904, a driver 906, a processor 908, and/or other subsystems or components 910. The semiconductor device assembly 902 can include features generally similar to those of the semiconductor device assemblies described above with reference to FIGS. 2-8. The resulting system 900 can perform any of a wide variety of functions, such as memory storage, data processing, and/or other suitable functions. Accordingly, representative systems 900 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 900 can also include remote devices and any of a wide variety of computer readable media.

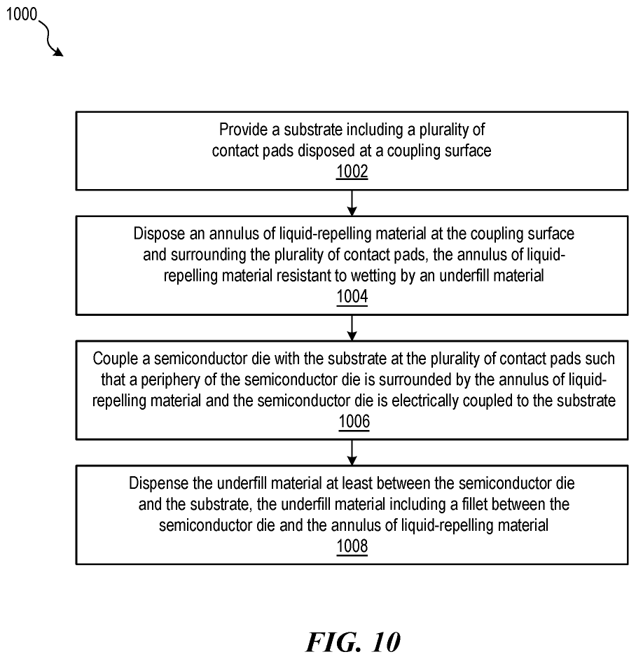

FIG. 10 illustrates an example method 1000 for fabricating a semiconductor device assembly in accordance with an embodiment of the present technology. The method 1000 may, for illustrative purposes, be described with respect to features, components, or elements of FIGS. 2-9. Although illustrated in a particular configuration, one or more operations of the method 1000 may be omitted, repeated, or reorganized. Additionally, the method 1000 may include other operations not illustrated in FIG. 10, for example, operations detailed in one or more other method described herein.

At 1002, a substrate 302 is provided. The substrate 302 may include a plurality of contact pads 308 disposed at a coupling surface. At 1004, a coating of liquid-repelling material 402 resistant to wetting by an underfill material 602 is disposed at the coupling surface. The coating of liquid-repelling material 402 surrounds the plurality of contact pads 308. In some implementations, disposing the coating of liquid-repelling material 402 includes using masking, screen printing, 3D printing, or dispensing. In some cases, the coupling surface of the substrate 302 may be etched to create an opening, and the liquid-repelling material may be disposed in the opening. At 1006, a semiconductor die 502 is coupled with the substrate 302 at the contact pads 308 such that a periphery of the semiconductor die is surrounded by the coating of liquid-repelling material 402 and the semiconductor die 502 is electrically coupled to the substrate 302. At 1008, the underfill material 602 is disposed at least between the semiconductor die 502 and the substrate 302. The underfill material 602 may include a fillet between the semiconductor die 502 and the coating of liquid-repelling material 402. In aspects, the underfill material 602 may be dispensed at a side of the semiconductor die 502 that is furthest from the coating of liquid-repelling material 402.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate having a plurality of contact pads disposed at a coupling surface;
a semiconductor die coupled with the substrate at the plurality of contact pads;
an annulus of liquid-repelling material disposed at the coupling surface and surrounding a periphery of the semiconductor die, the annulus of liquid-repelling material resistant to wetting by an underfill material; and
the underfill material disposed at least between the semiconductor die and the substrate, the underfill material including a fillet between the semiconductor die and the annulus of liquid-repelling material.

2. The semiconductor device assembly of claim 1, further comprising:
an additional semiconductor die mounted on the semiconductor die; and
a wire bond pad disposed at the coupling surface and configured to couple the additional semiconductor die with the substrate,
wherein the annulus of liquid-repelling material separates the underfill material from the wire bond pad.

3. The semiconductor device assembly of claim 1, further comprising:
a spacer disposed at the coupling surface; and
an additional semiconductor die mounted on the semiconductor die and the spacer;
wherein the annulus of liquid-repelling material separates the underfill material from the spacer.

4. The semiconductor device assembly of claim 1, wherein the annulus of liquid-repelling material forms a rectangular annulus surrounding the periphery of the semiconductor die.

5. The semiconductor device assembly of claim 1, wherein:
a first portion of the annulus of liquid-repelling material adjacent to a first side of the semiconductor die is distanced from the semiconductor die by a first distance; and
a second portion of the annulus of liquid-repelling material adjacent to a second side of the semiconductor die that is opposite the first side is distanced from the semiconductor die by a second distance that is different than the first distance.

6. The semiconductor device assembly of claim 5, wherein the first side of the semiconductor die corresponds to a side of the semiconductor die at which the underfill material is dispensed.

7. The semiconductor device assembly of claim 6, wherein the first distance is greater than the second distance.

8. The semiconductor device assembly of claim 1, wherein an upper surface of the annulus of liquid-repelling material is a height less than 10 microns from the coupling surface of the substrate.

9. The semiconductor device assembly of claim 1, wherein the annulus of liquid-repelling material is substantially coplanar with the coupling surface of the substrate.

10. The semiconductor device assembly of claim 1, wherein the annulus of liquid-repelling material has a width of at least 200 microns.

11. The semiconductor device assembly of claim 1, wherein the underfill material extends no more than 500 microns from the periphery of the semiconductor die.

12. The semiconductor device assembly of claim 1, wherein the liquid-repelling material comprises polytetrafluoroethylene (PTFE).

13. A method for fabricating a semiconductor device assembly, comprising:
providing a substrate including a plurality of contact pads disposed at a coupling surface;
disposing an annulus of liquid-repelling material at the coupling surface and surrounding the plurality of contact pads, the annulus of liquid-repelling material resistant to wetting by an underfill material;
coupling a semiconductor die with the substrate at the plurality of contact pads such that a periphery of the semiconductor die is surrounded by the annulus of liquid-repelling material and the semiconductor die is electrically coupled to the substrate; and
disposing the underfill material at least between the semiconductor die and the substrate, the underfill material including a fillet between the semiconductor die and the annulus of liquid-repelling material.

14. The method of claim 13, wherein disposing the underfill material between the semiconductor die and the substrate includes dispensing the underfill material at a side of the semiconductor die that is furthest from the annulus of liquid-repelling material.

15. The method of claim 13, wherein disposing the annulus of liquid-repelling material includes using masking, screen printing, three-dimensional printing, or dispensing.

16. The method of claim 13, wherein disposing the annulus of liquid-repelling material includes:
etching the substrate at the coupling surface to create an opening; and
disposing the liquid-repelling material in the opening.

17. A substrate, comprising:
an upper surface having:
a plurality of contact pads;
a wire bond pad;
a spacer; and
an annulus of liquid-repelling material surrounding the plurality of contact pads and separating the plurality of contact pads from the wire bond pad and the spacer, the liquid-repelling material resistant to wetting by an underfill material.

18. The substrate of claim 17, wherein the annulus of liquid-repelling material has a thickness less than 10 microns.

19. The substrate of claim 17, wherein the liquid-repelling material has a width of at least 200 microns.

20. The substrate of claim 17, wherein the liquid-repelling material comprises polytetrafluoroethylene (PTFE).
